(19) United States
(12) Patent Application Publication
(10) Pub. No.: US 2013/0081670 A1
(43) Pub. Date: Apr. 4, 2013

(54) PHOTOCELL

(71) Applicants: Timothy Ashley, Malvern (GB); Neil Thomson Gordon, Powick (GB); Janet Elizabeth Hails, Worcester (GB)

(72) Inventors: Timothy Ashley, Malvern (GB); Neil Thomson Gordon, Powick (GB); Janet Elizabeth Hails, Worcester (GB)

(73) Assignee: QINETIQ LIMITED, Farnborough, Hampshire (GB)

(21) Appl. No.: 13/496,409

(22) PCT Filed: Sep. 24, 2010
(86) PCT No.: PCT/GB2010/001797

§ 371 Date: Sep. 28, 2012

(30) Foreign Application Priority Data
Sep. 24, 2009 (GB) 0916759.4
Sep. 24, 2009 (GB) 0916760.2

(51) Int. Cl. H01L 31/0296; H01L 31/18; H01L 27/142

(52) U.S. Cl. CPC H01L 31/0296; H01L 27/1422; H01L 31/1828
USPC 136/246; 257/443; 438/80; 136/244

(57) ABSTRACT

An improved photocell offering efficient power generation from broadband incident radiation, the photocell includes a first diode formed in single crystal silicon and one or more further diodes each formed in a single crystal Group II-VI semiconductor. In a preferred embodiment, a tandem photocell is provided that incorporates a first diode formed in single crystal silicon, a second diode formed in a Group II-VI semiconductor, an optional buffer layer and a highly doped layer of silicon acting as an optional tunnel junction between the two diodes. The device can additionally include a layer of silicon deposited at the rear of the structure to maximise current collection of longer wavelength light, and top and bottom (front and back) electrical contacts. In use, light impinges on the top (front) surface of the photocell and is absorbed (in turn) by diodes.

This invention relates generally to a photocell, that is an apparatus for converting incident optical radiation to electrical energy, and in particular to a photocell which operates at multiple wavelengths for efficient power generation from broadband incident radiation such as the solar flux.

Photocells, also referred to as solar cells, are well known for providing electrical energy from incident optical radiation, in particular sunlight.

A well known type of photocell uses a semiconductor p-n junction arrangement. The conversion of optical energy into electrical energy using such a photocell is most efficient for photon energies slightly above the band gap of the semiconductor material used. If the photon energy is less than the band gap it is not absorbed and if it is significantly larger than the band gap, the excess energy (above the band gap) will be wasted as heat. For photocells designed to work with a single wavelength of illuminating radiation the band gap can be matched to the wavelength of the source. However, the spectrum of solar radiation extends over a range of wavelengths from about 0.3 μm to 5 μm.

In order to increase efficiency, photocells have been made consisting of several junctions in series stacked vertically. Each junction has a different band gap and so is tuned to a different wavelength of radiation. The junctions are arranged such that the junction with the largest band gap is outermost. Radiation with the highest energy is absorbed by this outermost junction and radiation with energies below the band gap is transmitted through to be absorbed by a lower junction.

Multiple junction devices of this type have been reported in Group III-V semiconductor systems and have shown increased efficiency as compared to a single junction approach. Whilst such a multiple junction approach is achievable with Group III-V semiconductor systems such as InGaP/InGaAs/Ge, however, it has so far not been feasible with Group II-VI semiconductors such as CdTe or HgCdTe. Group II-VI semiconductors span a larger range of band gaps than Group III-V semiconductors and accordingly, have band gaps that are better suited to the solar radiation.

It is an object of the present invention to provide an improved photocell utilising Group II-VI semiconductors.

According to a first aspect of the present invention, there is provided a photocell comprising a first diode formed in single crystal silicon and one or more further diodes each formed in a single crystal Group II-VI semiconductor, wherein the one or more further diodes are positioned on the first diode so as to form a stacked structure, and wherein each of the one or more further diodes has a different band gap, said band gap being higher than the band gap of the first diode, and wherein the respective diodes are arranged in order of increasing band gap such that the diode having the highest band gap is outermost. In order that each of the one or more further diodes has a different band gap, each of the one or more further diodes is desirably formed from a different Group II-VI semiconductor.

By Group II-VI semiconductor is meant a material comprising the Group IIA elements (preferably selected from Be, Mg and Ca) and/or the Group IIB elements (that is, selected from Zn, Cd and Hg) in combination with the Group VI elements (preferably selected from O, S, Se and Te). Put another way, the Group II-VI semiconductor is a compound semiconductor comprising at least one Group IIA and/or Group IIB element and at least one Group VI material as defined above. The Group II-VI semiconductor may be a binary material such as, for example, CdTe or CdSe, a ternary material such as, for example, CdZnTe, a quaternary material such as, for example, CdZnTeSe, and so on.

Group II-VI semiconductor as used in the invention may, in some circumstances, encompass a combination of different Group II-VI materials, which materials may be deposited, for example, as different material layers. However, although a Group II-VI semiconductor diode can comprise layers of different materials (one example being a mixed CdSe/CdTe diode) it is preferred that the one or more further diodes of the invention are individually formed from just one Group II-VI semiconductor. Forming the diode from suitably doped, single crystal layers of the same Group II-VI semiconductor provides a uniform lattice structure and accordingly, can optimise diode performance. Put another way, homojunctions are preferred over heterojunctions in the photocell of the invention. In prior art Group III-V photocells, heterojunction diodes are often implemented.

The skilled person will be aware that the Group IIA elements defined above are sometimes referred to as the Group IIB elements, and vice versa. Other naming conventions may exist.

Conveniently, the one or more further diodes—which are typically p-n and/or p-i-n junctions—are formed from doped layers of the Group II-VI semiconductor.

Group II-VI semiconductors that have been used in solar cell applications include ZnSe, CdS, ZnO and CdZnS (typically as window materials), CdTe, CdZnTe and CdMgTe (as absorber layers) and ZnTe (as a window material and/or back contact). ZnS and CdSe have also been used in solar cells, and there has been some interest in MgTe because it has a wide band gap and is lattice matched to CdTe and HgTe. In the photocell of the present invention, the one or more further diodes are each formed in a Group II-VI semiconductor having a higher band gap than silicon (in other words, a band gap in excess of 1.1 eV) and are arranged in order of increasing band gap such that the semiconductor diode with the highest band gap is outermost. In theory, any Group II-VI semiconductor having a higher band gap than silicon can be used in the invention, but preferably the one or more further diodes comprise one or more Group II-VI semiconductors selected from the group consisting of the aforementioned compounds (that is, ZnSe, CdS, ZnO, CdZnS, CdTe, CdZnTe, CdMgTe, ZnTe, ZnS, CdSe, MgTe), CdO, CdTeSe, CdZnSe and CdZnTeSe.

Silicon has a band gap of 1.1 eV, which gives a theoretical efficiency of about 28% for a single junction device assuming a perfect black body source and 100% efficient absorption. Although the band gap of silicon is not ideally matched to the solar spectrum, it has been widely implemented as a photovoltaic material and recent devices made from single crystal silicon have been shown to have an efficiency of up to about 22%. The band gap of silicon is close to the peak in the solar spectrum, but it is an indirect band gap material.

Group II-VI semiconductors can have band gaps that are well matched to the solar spectrum, but have so far achieved only limited use as photovoltaic materials. CdTe in particular has long been regarded as a near-ideal solar cell material (because its band gap of 1.49 eV lies close to the peak in the solar spectrum, with a theoretical efficiency of about 25%, and it is a very efficient absorber of radiation) but—even so—it is typically used in cheaper, lower efficiency polycrystalline thin film devices comprising glass substrates.

In the present invention, it is not attempted to provide a photocell made entirely from Group II-VI semiconductors. Instead, one or more diodes formed in a Group II-VI semiconductor are used to enhance the operating efficiency of a high efficiency, single crystal, silicon solar cell. This is achieved by providing a photocell comprising a first diode formed in single crystal silicon and one or more further diodes formed in a single crystal Group II-VI semiconductor, wherein the one or more further diodes are positioned on the first diode so as to form a stacked structure, and wherein each of the one or more further diodes has a different band gap, said band gap being higher than the band gap of the first diode, and wherein the respective diodes are arranged in order of increasing band gap such that the diode having the highest band gap is outermost. In this way, a multiple junction cell is formed from silicon and the one or more Group II-VI diodes which can maximise the conversion of solar energy into electricity.

Optimum gains in cell efficiency can be achieved when the innermost diode of the one or more further diodes (that is, the diode lying closest to the first diode) is formed in a Group II-VI semiconductor having a band gap close to the maximum in the solar spectrum. Accordingly, the innermost of the one or more further diodes is preferably formed in a Group II-VI semiconductor selected from the group consisting of ZnTe, CdTe, CdSe, CdS, ZnSe and MgTe, and related ternaries and quaternaries such as, for example, CdZnTe, CdTeSe, CdZnSe and CdZnTeSe. The Group II-VI semiconductor materials having the closest match to the solar spectrum are CdTe, CdSe and CdZnTe and hence, are more preferred materials. Most preferably, the innermost diode is formed from CdTe.

Preferably, the first diode is formed in a silicon wafer, more preferably a silicon wafer suitable for use in a conventional high efficiency solar cell, and the one or more further diodes are formed in a Group II-VI semiconductor region grown thereon, said region comprising—as necessary—one, two, three, four or even five different Group II-VI materials. This provides the advantage that a silicon wafer comprising a standard, high efficiency silicon cell can be taken prior to deposition of top contacts and adapted to form the enhanced photocell of the invention. The Group II-VI diodes are grown in order of increasing band gap, with the lowest band gap diode closest to the first diode and the highest band gap diode outermost. Conveniently, the Group II-VI semiconductor region is grown as epitaxial layers, said layers being doped to provide the required device structure.

The one or more further diodes are arranged in order of increasing band gap such that the diode having the highest band gap is outermost (that is, at the front of the cell). In use, the device is illuminated from the Group II-VI side of the photocell. Radiation with the highest energy is absorbed by the outermost diode and radiation with energies below the band gap is transmitted through to be absorbed by a lower diode. This higher energy radiation can be converted into electrical energy more efficiently than if it were absorbed directly in the silicon because the band gap is more closely matched to the radiation energy. Hence, the combined structure has an efficiency in excess of a silicon cell alone.

In order that the photocell of the invention operates at the highest possible efficiency, it is desirable that crystallographic defects are minimised. Accordingly, the diodes are fabricated from single crystal materials. Solar cells made from single crystal wafers of silicon are well known and can be used—prior to deposition of contacts—as substrates for the growth of single crystal layers of one or more Group II-VI semiconductors, thereby enabling straightforward fabrication of the device of the invention. Any suitable technique can be used for the growth of the one or more Group II-VI semiconductors such as, for example, metal-organic chemical vapour deposition (MOCVD), metal-organic vapour phase epitaxy (MOVPE), chemical vapour deposition (CVD) or molecular beam epitaxy (MBE).

In theory, the photocell of the invention can comprise one, two, three or even four further diodes, each diode having a progressively higher band gap. In other words, the photocell can comprise two, three, four or even five photovoltaic junctions. Preferably, however, the photocell is a tandem—or two-junction—device comprising a first diode formed in single crystal silicon and only one further diode (in other words, a second diode) formed in a single crystal Group II-VI semiconductor. A tandem device can be advantageous because it minimises the potential for spectral mismatch between the cells. This can be a problem for prior art multiple junction devices formed from Group III-V materials, which can often be current matched at only one value of the solar spectrum. Because the solar spectrum varies through the year, a tandem cell according to the preferred arrangement of the invention provides a higher potential for energy capture through the year.

For a tandem cell, it will be clear that the terms ‘outermost diode’, ‘innermost of the one or more further diodes, ‘second diode’ and ‘one further diode’ have equivalent meanings.

In a particularly preferred embodiment of the invention, the photocell is a tandem device and the second diode is formed from CdTe (which has a band gap of 1.49 eV), CdSe (which has a band gap of 1.74 eV) or CdZnTe (which has a band gap of 1.49 eV to 2.2 eV depending on the precise ratio of Cd to Zn). More preferably, the second diode is formed from CdTe, which is most closely matched to the solar maximum. In the latter embodiment, CdTe absorbs radiation above 1.49 eV and the silicon absorbs radiation between 1.1 and 1.49 eV. By combining the two materials, a tandem photocell can be fabricated with an efficiency around 33%.

In order to produce a working photocell, the first diode and one or more further diodes generally need to be connected in series and biased in the same direction. When the diodes are p-n and/or p-i-n junctions, the device can be oriented such that the n-doped regions are outermost—that is, on the side of each junction where radiation is incident -or such that the p-doped regions are outermost. The particular polarity chosen depends on the Group II-VI semiconductors selected for the photocell, the ease of growing said materials on the silicon, and/or the ease of doping the semiconductor materials to form a working photocell.

If the diodes are connected in series, a tunnel junction is preferably formed between each diode so as to provide efficient electrical contact between the different regions. One way of forming a tunnel junction is to deposit an additional, appropriately doped material layer between the two junctions. In Group III-V photocells, tunnel junctions are typically formed in a layer of the higher band gap material. However, the inventors have found that, because of dopant diffusion effects in Group II-VI materials, it can be difficult to form a tunnel junction. As a result, it is preferable to avoid forming a tunnel junction in the Group II-VI material and instead, the tunnel junction between the first diode and the innermost of the one or more further diodes is preferably formed in the silicon. Suitably, the tunnel junction takes the form of a highly doped silicon layer deposited on the first diode, said layer having a doping level typically in excess of 10¹⁷ cm⁻³. Desirably, the thickness of each tunnel junction is minimised so as to reduce possible radiation losses. For a tandem photocell, the thickness of the tunnel junction between the first diode and the second Group II-VI diode is preferably less than about 1 μm.

Alternatively, and indeed preferably in some circumstances, power can be taken out of the first diode and the one or more further diodes separately and combined externally. Difficulties can arise for multiple junction photocells connected in series, such as losses in device efficiency and difficulties with current matching. This can be ameliorated to some extent by bringing out the power from each junction separately and combining the power later, and also provides the advantage that tunnel junctions are not required between the first diode and one or more further diodes, and/or between each further diode. Accordingly, the device structure is simplified and overall efficiency improved. Preferably, the photocell includes one or more contact regions to draw current independently from each diode, the one or more contact regions preferably comprising a transparent conductor such as a conducting oxide. Examples of suitable conducting oxides are tin oxide (band gap 2.5-3 eV) or indium tin oxide. Power can then be efficiently extracted by shorting the contacts between the layers that would otherwise be provided with tunnel junctions. In other words, the layers are connected using external contacts rather than a tunnel junction.

It may be desirable to implement a combination of the above-mentioned approaches. In particular, it may be desirable to form a tunnel junction between the first diode and innermost of the one or more further diodes, preferably as a silicon layer as described above, and take power from any remaining diodes by means of external contacts.

In order to take up the lattice mismatch and hence, promote adhesion between the first diode and one or more further diodes, an intermediate buffer layer is desirable, said buffer layer being positioned between the first diode and innermost of the one or more further diodes. Generally, a buffer layer is chosen which has the same lattice type as the Group II-VI semiconductor from which the innermost diode is formed, and a compatible lattice parameter, and which also has a higher band gap (so that the buffer layer does not absorb radiation). Accordingly, the precise choice of buffer material depends on the particular semiconductor or semiconductors in which the one or more further diodes are formed. Typically, however, the buffer layer itself comprises a Group II-VI semiconductor material providing the required lattice matching, examples of suitable materials being ZnTe, CdTe, CdSe, CdS, ZnSe and related ternaries and quaternaries (such as, for example, CdZnTe). In the particular case of the innermost diode being formed from CdTe, a preferred buffer layer is ZnTe. In the particular case of the innermost diode being formed from CdSe, a preferred buffer layer is ZnSe or CdS.

The buffer layer needs to be a single crystal material, so that a single crystal Group II-VI can be grown on top, and ideally, the buffer layer is as thin as possible to reduce optical absorption and to facilitate electrical contact between the first diode and one or more further diodes. Preferably, the buffer layer has a thickness of less than about 1 μm, more preferably less than about 0.5 μm and even more preferably less than about 0.1 μm. Most preferably the buffer layer has a thickness in the range 20-50 nm.

The first diode can be a conventional silicon p/n+ diffusion, optionally having a highly doped p+ layer deposited onto the n+ surface to form a tunnel junction. It has been found that the presence of the optional p+ layer does not inhibit the sharpness of the junction, and the p/n+ diffusion still works as a solar cell. A p+ layer can also be deposited at the rear of the structure to maximise current collection of longer wavelength light. Typical dimensions for the p/n+ region of a conventional silicon cell are 200 μm p Si/0.5 μm n+ Si.

Alternatively, the first diode structure can be a silicon (p or n)/p+ diffusion, optionally having a highly doped n+ layer deposited onto the p+ surface to form a tunnel junction. An n+ layer can be deposited at the rear of the structure to maximise current collection of longer wavelength light.

Some prior art methods for growing epitaxial layers of Group II-VI materials onto silicon use a silicon substrate with the (211) orientation. However, this Si orientation is not compatible with standard silicon solar cells. In the present invention, the silicon wafer is instead preferably (001) misaligned towards <111>, with a degree of misalignment between 2° and 10° being acceptable. The mis-orientation has been found to have negligible effect on solar cell efficiency, but is advantageous for crystal growth.

The photocell can additionally comprise top and/or bottom (that is, front and/or back) contacts. A single junction silicon solar cell normally has a metal grid on the front (typically n+) surface consisting of two strips—or bus bars—about 1.5 mm wide traversing the cell, with narrow grid lines about 100 μm wide running at right angles to the bus bars across the full cell width. In the present invention, there is no metal grid on the outer surface of the first diode, but instead a metal grid can be positioned on top of the outermost Group II-VI diode (the outermost diode being the second diode for a tandem cell). The metal grids can comprise commonly used contact metals such as Ag, Ti/Pd/Ag and Ni/Cu/Ag, but in some applications it is preferred to avoid the use of Ag and Cu because they can act as Group II-VI dopants. In such applications, Au and Cr may be preferred contact metals. Alternatively, a transparent conducting oxide film with superimposed grid can be deposited on top of the outermost diode. The bottom, or back, contact can be any suitable contact arrangement known for silicon solar cells.

The skilled person will be well aware of the elements commonly used for doping silicon and Group II-VI semiconductors and—in theory—any known dopants can be used in the device of the invention to implement the desired diode structures. Preferably, however, the Group II-VI materials of the one or more further diodes and optional buffer layer are doped with N, As, P and Sb—for p-type doping—and In, CI, Br and I—for n-type doping. More preferably, the Group II-VI materials are doped with As and/or I.

Suitably, layers of Group II-VI semiconductor materials (from which the diodes and optional buffer layer are typically formed) are doped at a level between 10¹⁵ and 10¹⁸ cm⁻³, n+ and p+ layers being at the higher end of the range and n and p layers being toward the mid- to lower end of the range. The optional buffer layer preferably needs to be as highly doped as possible, to ensure electrical contact is made.

The thickness of the one or more further diodes can be optimised for a particular material system and application, but typically the thickness of the absorbing layer is comparable with the wavelength of the light being absorbed. For a tandem device having a p-i-n diode formed from CdTe, the thickness of the absorbing (intrinsic) layer is typically around 1-3 μm, and the thickness of the total p-i-n structure is typically around 2-5 μm.

A resistivity of 1 Ohm cm p type is normal for Si solar cells, although it is possible and even desirable in some instances to use 10 Ohm cm material.

In a preferred embodiment of the invention, a photocell has the following tandem cell structure:

n+CdTe/(p or n)CdTe/p+CdTe/pZnTe/p+Si/n+Si/pSi/p+Si

The n+Si/p Si layers comprise the first diode and the n+CdTe/(p or n)CdTe/p+ CdTe layers comprise a second diode. A buffer layer comprising p-doped ZnTe is positioned between the first and second diodes, together with a highly doped layer of p-type silicon (p+ Si) to form a tunnel junction. An additional p+ Si layer is deposited at the rear of the structure to maximise current collection from longer wavelength light. Absorption of radiation takes place in the lower doped (p or n) CdTe layer and the low doped (p Si) layer in the silicon.

The tandem CdTe photocell can be configured with alternative polarity, as follows:

p+CdTe/(p or n)CdTe/n+CdTe/nZnTe/n+Si/p+Si/(p or n)Si/n+Si

The p+ Si/(p or n) Si layers comprise the first diode and the p+ CdTe/(p or n) CdTe/n+ CdTe layers comprise the second diode. A buffer layer comprising n-doped ZnTe is positioned between the first and second diodes, together with a highly doped layer of n-type silicon (n+ Si) to form a tunnel junction. An additional n+ Si layer is deposited at the rear of the structure to maximise current collection from longer wavelength light.

Absorption of radiation takes place in the lower doped (p or n) CdTe layer and the low doped (p or n Si) layer in the silicon.

Alternative (although generally less efficient) dual cell structures are:

n+CdSe/(p or n)CdSe/p+CdSe/pCdS/p+Si/n+Si/pSi /p+Si

p+CdSe/(p or n)CdSe/n+CdSe/nCdS/n+Si/p+Si/(p or n) Si/n+Si

n+CdSe/(p or n)CdSe/p+CdSe/pZnSe/p+Si/n+Si/pSi/p+Si

p+CdSe/(p or n)CdSe/n+CdSe/nZnSe/n+Si/p+Si/(p or n) Si/n+Si

In the first and second of the above-mentioned alternative structures, the second diode comprises CdSe and the buffer layer comprises CdS. In the third and fourth structures, the second diode comprises CdSe and the buffer layer comprises ZnSe.

All of the example structures described above comprise diodes that are homojunctions rather than heterojunctions.

According to a second aspect of the present invention, there is provided a tandem photocell comprising a first diode formed in single crystal silicon, a second diode formed in a single crystal Group II-VI semiconductor, the second diode being positioned on the first diode so as to form a stacked structure with the second diode outermost, a single crystal buffer layer positioned between the first diode and the second diode and a tunnel junction between the first and second diodes, wherein the tunnel junction is formed as a doped layer of silicon between the first diode and buffer layer, and wherein the second diode has a higher band gap than the first diode. Preferably the second diode comprises CdTe and the buffer layer comprises ZnTe.

According to a third aspect of the present invention, there is provided a photovoltaic array comprising two or more photocells as described above in relation to the first and second aspects.

According to a fourth aspect of the invention, there is provided a concentrating solar system comprising one or more photocells as described above in relation to the first and second aspects, and means for concentrating solar radiation onto said one or more photocells. It well known to incorporate photovoltaic cells into systems which concentrate the solar radiation onto the cells and the skilled person will be aware of suitable means for concentrating the solar radiation. An example is a magnifying lens such as, for example, a Fresnel lens.

According to a fifth aspect of the present invention, there is provided a method of producing a photocell comprising the steps of:
(i) providing a single crystal silicon wafer comprising a first diode; and
(ii) epitaxially growing one or more further diodes on the first diode so as to form a stacked structure, said one or more further diodes being formed in a Group II-VI semiconductor,
   wherein each of the one or more further diodes have a different band gap, said band gap being higher than the band gap of the first diode,

and wherein the respective diodes are arranged in order of increasing band gap such that the diode having the highest band gap is outermost.

A photocell according to the first aspect of the invention typically comprises different epitaxial layers of n- and/or p-type Group II-VI materials, with different thicknesses and doping concentrations. In the method of the fifth aspect, the first diode is formed in a silicon wafer, more preferably a silicon wafer suitable for use in a conventional high efficiency solar cell, and the one or more further diodes are formed in a Group II-VI semiconductor region grown thereon. This provides an efficient and straightforward fabrication method whereby a standard, high efficiency silicon cell can be taken prior to deposition of top contacts and adapted to form the enhanced photocell of the invention.

The Group II-VI semiconductor can be any Group II-VI semiconductor having a higher band gap than silicon, but preferably the one or more further diodes comprise one or more Group II-VI semiconductors selected from the group consisting of ZnSe, CdS, ZnO, CdZnS, CdTe, CdZnTe, CdMgTe, ZnTe, ZnS, CdSe, MgTe, CdO, CdTeSe, CdZnSe and CdZnTeSe.

The innermost of the one or more further diodes is preferably formed in a Group II-VI semiconductor selected from the group consisting of ZnTe, CdTe, CdSe, CdS, ZnSe and MgTe, and related ternaries and quaternaries such as, for example, CdZnTe, CdTeSe, CdZnSe and CdZnTeSe. The Group II-VI semiconductor materials having the closest match to the solar spectrum are CdTe, CdSe and CdZnTe and hence, are more preferred materials. Most preferably, the innermost diode is formed from CdTe.

In a particularly preferred embodiment, one further—or second—diode is epitaxially grown on the first diode so as to form a tandem photocell. Preferred semiconductors for the second diode are listed above in relation to the innermost diode.

The epitaxial layers can be grown by any suitable process such as, for example, MOCVD, MOVPE, MBE, CVD or any combination thereof. Preferably, the layers are gown by MBE and/or MOVPE, which are well-established techniques for Group II-VI materials, and even more preferably the device is grown in a single MBE or MOVPE process (that is, all of the layers are grown either by MBE or MOVPE). Growth of Group II-VI materials on silicon has been described previously and the skilled person will be well aware of possible growth techniques.

In certain situations, MBE can be a preferred method of crystal growth because the technique not only allows epitaxial layers having the desired doping levels to be grown, but the equipment can also be operated at the elevated temperatures and under the background ambient conditions required to establish the cleanliness of the silicon substrate prior to the start of deposition. However, MOVPE can also be a particularly advantageous technique, particularly in regard to scale-up, reliability and cost reduction.

MBE growth of the epitaxial layers can be carried out by evaporation from the compound sources (for example, from ZnTe for growth of a ZnTe buffer layer, and/or from CdTe for growth of a CdTe semiconductor layer). The epitaxial layers can also be grown from the constituent Group II-VI elements such as, for example, Zn and Te for ZnTe, and Cd and Te for CdTe. In the particular case of growing CdTe, it is desirable that a cadmium overpressure is established to achieve active doping. Accordingly, growth conditions are preferably modified so that epitaxial CdTe layers are grown from a combination of cadmium telluride and cadmium, or from Cd and Te with a Cd flux in excess. Preferably, the overpressure is established before the dopants are introduced.

Any suitable precursors can be used for MOVPE growth of the epitaxial layers. Preferred precursors for CdTe growth by MOVPE are dimethylcadmium and di-iso-propyl telluride, typically in hydrogen carrier gas, or dimethylcadmium and diethyltelluride, again typically in hydrogen carrier gas.

In theory, any dopant source suitable for the chosen crystal growth technique can be used. Hence, dopant sources for MBE might include As₄, As₂, Cd₃As₂, Cdl₂, Znl₂, Agl₂ or metallic In, and for MOVPE might include tris(dimethyl)aminoarsenic, or an alkyl iodide such as, for example, isobutyliodide (1-iodo-2-methylpropane). In practice, however, it has been found that active p-doping and n-doping of Group II-VI semiconductors can be difficult to achieve. Accordingly, appropriate selection of dopant source is important in the present invention. For MBE growth of Group II-VI materials containing cadmium (such as, for example, CdTe) it has been found that cadmium overpressure significantly improves the dopant activation, because it ensures no Cd vacancies (which would otherwise compensate the doping activity). Hence, cadmium-rich materials such as cadmium iodide (Cdl₂) for n-doping, and cadmium arsenide (Cd₃As₂) for p-doping are particularly preferred. A further advantage of using Cdl₂ and/or Cd₃As₂ is that the dopant compound forces the I and/or As to reside at the correct sites in the CdTe lattice, again improving doping activation.

One disadvantage of using the preferred cadmium-rich compounds as dopants is that their volatility makes them difficult to handle in an ultra-high vacuum environment. Hence, a preferred MBE cell for use in the method of the invention has a small volume (only a few cm³) and is fitted with a valve to control release of the dopant source. Controlled release is important so as to prevent the dopant source material escaping into the growth chamber, vacuum system and/or growing layers when not required. Automation of the valve significantly improves reproducibility and throughput of samples.

Any feature in one aspect of the invention may be applied to any other aspects of the invention, in any appropriate combination. In particular, device aspects may be applied to method aspects, and vice versa.

The invention extends to a photocell and method substantially as herein described with reference to the accompanying drawings.

The invention will now be described, purely by way of example, with reference to the accompanying drawings, in which;

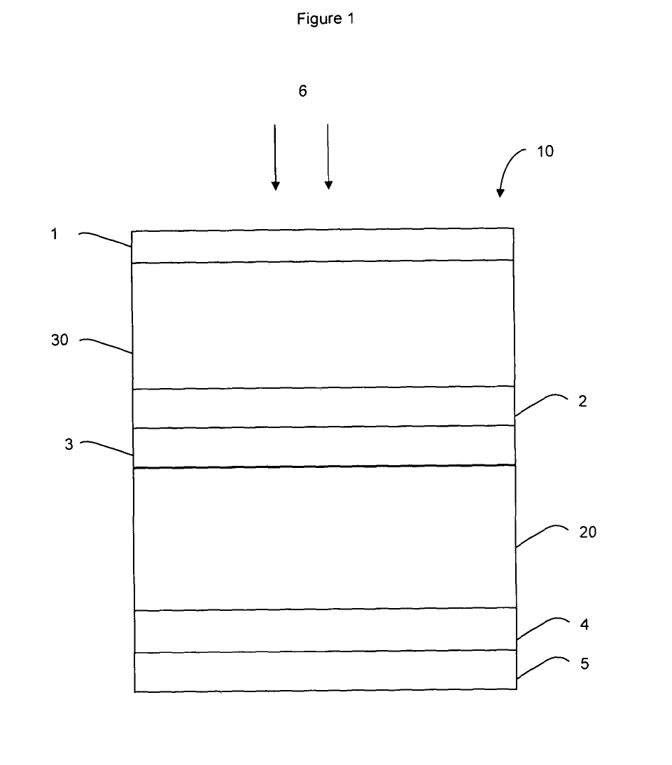

FIG. 1 is a schematic, cross-sectional representation of a photocell according to a preferred embodiment of the invention; and

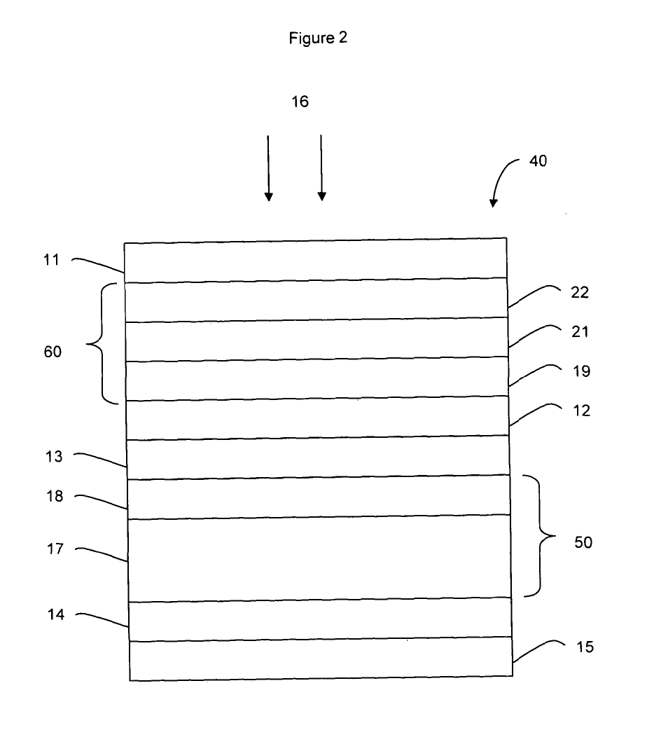

FIG. 2 is a schematic, cross-sectional representation of a tandem photocell showing device structure in more detail.

FIG. 1 (not to scale) illustrates a tandem photocell 10 incorporating a first diode 20 formed in single crystal silicon, a second diode 30 formed in a Group II-VI semiconductor, an optional buffer layer 2 and a highly doped layer of silicon 3 acting as an optional tunnel junction between the two diodes. The device can additionally comprise a layer of silicon 4 deposited at the rear of the structure to maximise current collection of longer wavelength light, and top and bottom (front and back) electrical contacts 1 and 5. In use, light 6 impinges on the top (front) surface of the photocell and is absorbed (in turn) by diodes 30 and 20.

FIG. 2 (not to scale) illustrates the structure of a preferred tandem photocell 40 in more detail. A first diode 50 takes the form of a p/n+ diffusion and comprises a layer of p-type silicon 17 and a layer of n+silicon 18. The second diode 60 is a p-i-n junction comprising a highly doped layer of p-type CdTe 19, a p- or n- doped layer of CdTe 21 and a highly doped layer of n-type CdTe 22.

The silicon and CdTe device regions are connected by a p-doped ZnTe buffer layer 12, and a highly doped p-type silicon layer 13 acts as a tunnel junction between the two diodes.

An additional p+ Si layer 14 is deposited at the rear of the structure to maximise current collection of longer wavelength light, and the device comprises top and bottom electrical contacts 11 and 15. In use, light 16 impinges on the top surface and is absorbed (in turn) by layers 21 and 17.

The silicon layers are doped using standard industrial dopants (for example, the silicon n+ surface 18 is phosphorus doped). The CdTe and ZnTe layers are doped p-type with arsenic and CdTe is doped n-type with iodine.

In an alternative embodiment, the first diode 50 takes the form of a p/n+ silicon diffusion as described above, the second diode 60 is a p-i-n junction comprising a highly doped layer of p-type CdSe 19, a p- or n- doped layer of CdSe 21 and a highly doped layer of n-type CdSe 22, and the buffer layer 12 comprises p-doped CdS. A highly doped p-type silicon layer again acts as a tunnel junction between the two diodes. The buffer layer 12 can alternatively be formed from p-type ZnSe.

In yet another embodiment, a tandem photocell can be provided with the opposite bias. The first diode 50 takes the form of a n/p+ diffusion and comprises a layer of p- or n-type silicon 17 and a layer of p+ silicon 18. The second diode 60 is an n-i-p junction comprising a highly doped layer of n-type CdTe 19, a p- or n- doped layer of CdTe 21 and a highly doped layer of p-type CdTe 22.

The silicon and CdTe device regions are connected by an n-doped ZnTe buffer layer 12, and highly doped n-type silicon layer 13 acts as a tunnel junction between the two diodes.

An additional n+ Si layer 14 is deposited at the rear of the structure to maximise current collection of longer wavelength light. The silicon layers are doped using standard industrial dopants and the p-type and n-type layers of the CdTe and ZnTe layers are doped (respectively) with arsenic and iodine.

The Si-CdSe photocell described above can also be configured in reverse bias.

It will be clear to the skilled person that the Group II-VI semiconductors materials comprising the second diode and buffer layer can be varied to provide a variety of different devices.

The invention has been described with specific reference to solar cells. It will be understood that this is not intended to be limiting and the invention may be used more generally with photocells, for example with a thermo-photovoltaic converter which uses other hot sources to generate electrical power.

1. A photocell comprising a first diode formed in single crystal silicon and one or more further diodes each formed in a single crystal Group II-VI semiconductor, wherein the one or more further diodes are positioned on the first diode so as to form a stacked structure, and wherein each of the one or more further diodes has a different band gap, said band gap being higher than the band gap of the first diode, and wherein the respective diodes are arranged in order of increasing band gap such that the diode having the highest band gap is outermost.

2. A photocell according to claim 1, wherein each of the one or more further diodes is formed from a different Group II-VI semiconductor.

3. A photocell according to claim 1, wherein the one or more further diodes are individually formed from one Group II-VI semiconductor.

4. A photocell according to claim 1, wherein the one or more further diodes are formed from doped layers of the Group II-VI semiconductor.

5. A photocell according to claim 1, wherein the first diode is formed in a silicon wafer and the one or more further diodes are formed in a Group II-VI material region grown thereon.

6. A photocell according to claim 5, wherein the Group II-VI material region is grown as epitaxial layers.

7. A photocell according to claim 1, wherein the one or more further diodes comprise one or more Group II-VI semiconductors selected from the group consisting of ZnSe, CdS, ZnO, CdZnS, CdTe, CdZnTe, CdMgTe, ZnTe, ZnS, CdSe, MgTe, CdO, CdTeSe, CdZnSe and CdZnTeSe.

8. A photocell according to claim 1, wherein the innermost of the one or more further diodes comprises one or more Group II-VI semiconductors selected from the group consisting of ZnTe, CdTe, CdSe, CdS, ZnSe, MgTe, CdZnTe, CdTeSe, CdZnSe and CdZnTeSe.

9. A photocell according to claim 1, wherein the first diode and one or more further diodes are p-n and/or p-i-n junctions.

10. A photocell according to claim 9, wherein the p-type layers of the one or more further diodes comprise one or more dopants selected from N, As, P and Sb.

11. A photocell according to claim 9, wherein the n-type layers of the one or more further diodes comprise one or more dopants selected from In, Cl, Br and I.

12. A photocell according to claim 1, wherein the first diode and one or more further diodes are connected in series and biased in the same direction.

13. A photocell according to claim 12, further comprising one or more tunnel junctions between respective diodes.

14. A photocell according to claim 13, wherein the tunnel junction between the first diode and the innermost of the one or more further diodes is formed in the single crystal silicon.

15. A photocell according to claim 14, wherein the tunnel junction comprises a highly doped layer of silicon deposited on the first diode.

16. A photocell according to claim 1, wherein current is drawn from each diode by means of one or more contact regions.

17. A photocell according to claim 16, wherein the contact regions comprise a transparent conductor.

18. A photocell according to claim 1, further comprising a single crystal buffer layer between the first diode and the innermost of the one or more further diodes.

19. A photocell according to claim 18, wherein the buffer layer comprises a Group II-VI semiconductor.

20. A photocell according to claim 18, wherein the innermost of the one or more further diodes is formed from CdTe and the buffer layer comprises ZnTe.

21. A photocell according to claim 1, wherein the photocell is a tandem device comprising a first diode and one further diode.

22. A tandem photocell comprising a first diode formed in single crystal silicon, a second diode formed in a single crystal Group II-VI semiconductor, the second diode being positioned on the first diode so as to form a stacked structure with the second diode outermost, a single crystal buffer layer positioned between the first diode and the second diode and a tunnel junction between the first and second diodes, wherein the tunnel junction is formed as a doped layer of silicon between the first diode and buffer layer, and wherein the second diode has a higher band gap than the first diode.

23. A tandem photocell according to claim 22, wherein the second diode comprises CdTe and the buffer layer comprises ZnTe.

24. A photovoltaic array comprising two or more photocells according to claim 1.

25. A concentrating solar system comprising one or more photocells according to claim 1, and means for concentrating solar radiation onto said one or more photocells.

26. A method of producing a photocell comprising the steps of:
(i) providing a single crystal silicon wafer comprising a first diode; and
(ii) epitaxially growing one or more further diodes on the first diode so as to form a stacked structure, each of the one or more further diodes being formed in a Group II-VI semiconductor,
wherein the one or more further diodes each have a different band gap, said band gap being higher than the band gap of the first diode,
and wherein the respective diodes are arranged in order of increasing band gap such that the diode having the highest band gap is outermost.

27. A method according to claim 26, said method comprising the additional step of epitaxially growing a buffer layer between the first diode and innermost of the one or more further diodes.

28. A method according to claim 26, wherein at least one epitaxial layer of a Group II-VI material containing cadmium is grown.

29. A method according to claim 28, wherein the one or more further diodes are grown by MBE and cadmium overpressure is maintained during the growth of the at least one epitaxial layer.

30. A method according to claim 28, wherein the at least one epitaxial layer is doped with As and the dopant source is Cd3As2.

31. A method according to claim 28, wherein the at least one epitaxial layer is doped with I and the dopant source is Cdl2.

32. A method according to claim 30, wherein release of the dopant source is controlled so as to prevent the dopant source material escaping into the growth chamber, vacuum system and/or growing layers when not required.

33. A method according to claim 26, wherein the diodes are connected in series and the method comprises the additional step of forming one or more tunnel junctions between respective diodes.

34. A method according to claim 26, wherein one or more external contacts are provided to respective diodes so that power is extracted separately from each diode.

35. (canceled)

36. (canceled)

37. A photovoltaic array comprising two or more photocells according to claim 22.

38. A concentrating solar system comprising one or more photocells according to claim 22 and means for concentrating solar radiation onto said one or more photocells.
